(19) United States
(12) Patent Application Publication
(10) Pub. No.: US 2021/0375378 A1
(43) Pub. Date: Dec. 2, 2021

(54) MEMORY DEVICE AND METHOD OF OPERATING THE SAME

(71) Applicant: SK hynix Inc., Gyeonggi-do (KR)

(72) Inventor: Young Hwan CHOI, Gyeonggi-do (KR)

(21) Appl. No.: 17/065,113

(22) Filed: Oct. 7, 2020

(30) Foreign Application Priority Data
May 28, 2020 (KR) 10-2020-0064487

(51) Int. Cl. G11C 16/34; G11C 16/16; G11C 16/24; G11C 16/26; G11C 16/30

(52) U.S. Cl. CPC G11C 16/3472; G11C 16/16; G11C 16/30; G11C 16/26; G11C 16/24

(57) ABSTRACT

The present technology relates to a memory device and a method of operating the same. The memory device includes a memory block including a plurality of strings, a peripheral circuit configured to perform an erase operation including a first erase operation, an erase verify operation, and a second erase operation on the memory block, and a control logic configured to control the peripheral circuit to perform the erase operation. During the second erase operation, the control logic controls the peripheral circuit to apply a first erase voltage to a source line of the memory block and apply a second erase voltage, which is lower than the first erase voltage, to a bit line connected to a string determined as erase pass among the plurality of strings.

### CROSS-REFERENCE TO RELATED APPLICATION

The present application claims priority under 35 U.S.C. § 119(a) to Korean patent application number 10-2020-0064487, filed on May 28, 2020, which is incorporated herein by reference in its entirety.

### BACKGROUND

### Field of Invention

The present disclosure relates to an electronic device, and more particularly, to a memory device and a method of operating the same.

### Description of Related Art

Among semiconductor devices, memory devices are generally categorized into two types: volatile memory devices and non-volatile memory devices.

A write speed and a read speed of the non-volatile memory device are relatively slow; however, the non-volatile memory device continues to store data even though power supply is shut off. Therefore, a non-volatile memory device is used to store data to be maintained regardless of power supply. Examples of non-volatile memory devices include a read only memory (ROM), a mask ROM (MROM), a programmable ROM (PROM), an erasable programmable ROM (EPROM), an electrically erasable programmable ROM (EEPROM), a flash memory, a phase change random access memory (PRAM), a magnetic RAM (MRAM), a resistive RAM (RRAM), a ferroelectric RAM (FRAM), and the like. A flash memory may be a NOR type or a NAND type.

A flash memory has an advantage of a RAM that may freely program and erase data and an advantage of a ROM that may preserve stored data even though power supply is cut off. The flash memory is widely used as a storage medium of a portable electronic device such as a digital camera, a personal digital assistant (PDA), and an MP3 player.

### SUMMARY

An embodiment of the present disclosure provides a memory device capable of improving a threshold voltage distribution of memory cells during an erase operation of the memory device, and a method of operating the same.

A memory device according to an embodiment of the present disclosure includes a memory block including a plurality of strings, a peripheral circuit configured to perform an erase operation including a first erase operation, an erase verify operation, and a second erase operation on the memory block, and a control logic configured to control the peripheral circuit to perform the erase operation. During the second erase operation, the control logic controls the peripheral circuit to apply a first erase voltage to a source line of the memory block and apply a second erase voltage, which is lower than the first erase voltage, to a bit line connected to a string determined as erase pass among the plurality of strings.

A memory device according to an embodiment of the present disclosure includes a memory block including a plurality of strings, a peripheral circuit configured to perform an erase operation including a first erase operation, an erase verify operation, and a second erase operation on the memory block, and a control logic configured to control the peripheral circuit to perform the erase operation. During the second erase operation, the control logic controls the peripheral circuit to apply an erase voltage to a source line of the memory block and float a bit line connected to a string determined as erase pass among the plurality of strings.

A method of operating a memory device according to an embodiment of the present disclosure includes performing a first erase operation of applying a first erase voltage to a source line and bit lines of a selected memory block, determining whether each of a plurality of strings included in the selected memory block is erased, by performing an erase verify operation, and performing a second erase operation of applying the first erase voltage to the source line and applying a second erase voltage to a bit line of a string determined as erase pass when at least one string among the plurality of strings is determined as erase fail as a result of the erase verify operation.

A method of operating a memory device according to an embodiment of the present disclosure includes performing a first erase operation of applying an erase voltage to a source line and bit lines of a selected memory block, determining whether each of a plurality of strings included in the selected memory block is erased, by performing an erase verify operation, and performing a second erase operation of applying the erase voltage to the source line, floating a bit line of a string determined as an erase pass, and applying the erase voltage to a bit line of a string determined as an erase fail when at least one string among the plurality of strings is determined as the erase fail as a result of the erase verify operation.

A memory device according to an embodiment of the present disclosure includes a memory block including first and second strings of memory cells; control circuitry configured to perform a current erase operation on the memory block when the first string is verified as successful and the second string is verified as failed as a result of a previous erase operation, wherein the control circuitry applies a first erase voltage to a bit line of the second string and a source line of the memory block and a second erase voltage to a bit line of the first string, during the current erase operation, and wherein the second erase voltage is lower than the first erase voltage.

A memory device according to an embodiment of the present disclosure includes a memory block including first and second strings of memory cells; control circuitry configured to perform a current erase operation on the memory block when the first string is determined to have been successful and the second string is determined to have failed as a result of a previous erase operation, wherein the control circuitry applies an erase voltage to a bit line of the second string and a source line of the memory block and floats a bit line of the first string, during the current erase operation.

### BRIEF DESCRIPTION OF THE DRAWINGS

FIG. 1 is a diagram illustrating a memory system according to an embodiment of the present disclosure.

FIG. 2 is a diagram illustrating a memory device, such as that of FIG. 1.

FIG. 3 is a diagram illustrating a memory block, such as that of FIG. 2.

FIG. 4 is a diagram illustrating an embodiment of a three-dimensional memory block.

FIG. 5 is a diagram illustrating another embodiment of a three-dimensional memory block.

FIG. 6 is a diagram illustrating a page buffer, such as that of FIG. 2.

FIG. 7 is a flowchart illustrating an operation of the memory device according to an embodiment of the present disclosure.

FIG. 8 is a diagram illustrating application of a first erase voltage and a second erase voltage to a source line and a bit line during an erase operation according to an embodiment of the present disclosure.

FIG. 9 is a diagram illustrating another embodiment of a memory system including a memory device, such as that shown in FIG. 2.

FIG. 10 is a diagram illustrating another embodiment of a memory system including a memory device, such as that shown in FIG. 2.

FIG. 11 is a diagram illustrating another embodiment of a memory system including a memory device, such as that shown in FIG. 2.

FIG. 12 is a diagram illustrating another embodiment of a memory system including a memory device, such as that shown in FIG. 2.

### DETAILED DESCRIPTION

Specific structural and functional description provided herein is directed to embodiments of the present disclosure. The present invention, however, may be carried out in various ways and implemented in various forms. Thus, the present invention is not limited to or by any embodiment(s), nor to any specific detail described herein. Rather, the present invention is defined by the claims.

Hereinafter, embodiments of the present disclosure are described in detail with reference to the accompanying drawings, so that those skilled in the art to which the present disclosure pertains may practice and easily carry out the present invention. Throughout the specification, reference to “an embodiment,” “another embodiment” or the like is not necessarily to only one embodiment, and different references to any such phrase are not necessarily to the same embodiment(s). The term “embodiments” when used herein does not necessarily refer to all embodiments.

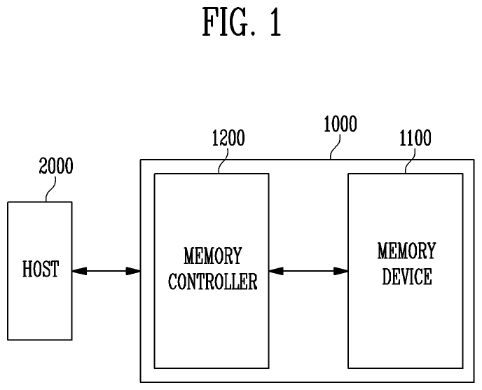

FIG. 1 is a diagram illustrating a memory system according to an embodiment of the present disclosure.

Referring to FIG. 1, the memory system 1000 includes a memory device 1100 in which data is stored, and a memory controller 1200 that controls the memory device 1100 under control of a host 2000.

The host 2000 may communicate with a the memory system 1000 by using an interface protocol such as a peripheral component interconnect-express (PCI-E), an advanced technology attachment (ATA), a serial ATA (SATA), a parallel ATA (PATA), or a serial attached small computer system interface (SCSI) (SAS). Other interface protocols that may be used for communication between the host 2000 and the memory system 1000 include universal serial bus (USB), a multi-media card (MMC), an enhanced small disk interface (ESDI), and integrated drive electronics (IDE). More generally, any suitable interface protocol may be used.

The memory device 1100 may perform a program, read, or erase operation under control of the memory controller 1200. The memory device 1100 may include a plurality of memory blocks, and may perform the program, read, and erase operations on a selected memory block among the plurality of memory blocks.

According to an embodiment of the present disclosure, the memory device 1100 performs a first erase operation in a gate induced drain leakage (GIDL) method by applying a first erase voltage to bit lines and a source line connected to a selected memory block. Thereafter, a second erase operation is performed after performing an erase verify operation. During the second erase operation, a second erase voltage lower than the first erase voltage is applied to a bit line corresponding to memory cells determined as erase pass among the bit lines according to a result of the erase verify operation and the first erase voltage is applied to a bit line corresponding to memory cells determined as erase fail according to a result of the erase verify operation. Therefore, a phenomenon in which the memory cells determined as having passed the erase operation are over-erased may be prevented or reduced.

The memory controller 1200 is connected between the host 2000 and the memory device 1100. The memory controller 1200 is configured to access the memory device 1100 in response to a request from the host 2000. For example, the memory controller 1200 is configured to control program, read, erase, and background operations of the memory device 1100 in response to the request received from the host 2000. The memory controller 1200 is configured to provide an interface between the memory device 1100 and the host 2000. The memory controller 1200 is configured to drive firmware for controlling the memory device 1100.

The memory controller 1200 and the memory device 1100 may be integrated into one semiconductor device to form a semiconductor drive (solid state drive (SSD)). The semiconductor drive (SSD) includes a storage device configured to store data in a semiconductor memory. When the memory system 1000 is used as the semiconductor drive (SSD), operation speed of the host 2000 connected to the memory system 1000 is dramatically improved.

In another example, the memory system 1000 is provided as one of various components of an electronic device such as a computer, an ultra-mobile PC (UMPC), a workstation, a net-book, a personal digital assistants (PDA), a portable computer, a web tablet, a wireless phone, a mobile phone, a smart phone, an e-book, a portable multimedia player (PMP), a portable game machine, a navigation device, a black box, a digital camera, a 3-dimensional television, a digital audio recorder, a digital audio player, a digital picture recorder, a digital picture player, a digital video recorder, and a digital video player, a device capable of transmitting and receiving information in a wireless environment, one of various electronic devices configuring a home network, one of various electronic devices configuring a computer network, one of various electronic devices configuring a telematics network, an RFID device, or one of various components configuring a computing system.

In an embodiment, the memory device 1100 or the memory system 1000 may be mounted as a package of any of various types. For example, the memory device 1100 or the memory system 1000 may be packaged and mounted in a method such as a package on package (PoP), ball grid arrays (BGAs), chip scale packages (CSPs), plastic leaded chip carriers (PLCC), a plastic dual in line package (PDIP), a die in waffle pack, die in wafer form, a chip on board (COB), a ceramic dual in line package (CERDIP), a plastic metric quad flat pack (MQFP), a thin quad flat pack (TQFP), a small outline (SOIC), a shrink small outline package (SSOP), a thin small outline (TSOP), a system in package (SIP), a multi-chip package (MCP), a wafer-level fabricated package (WFP), or a wafer-level processed stack package (WSP).

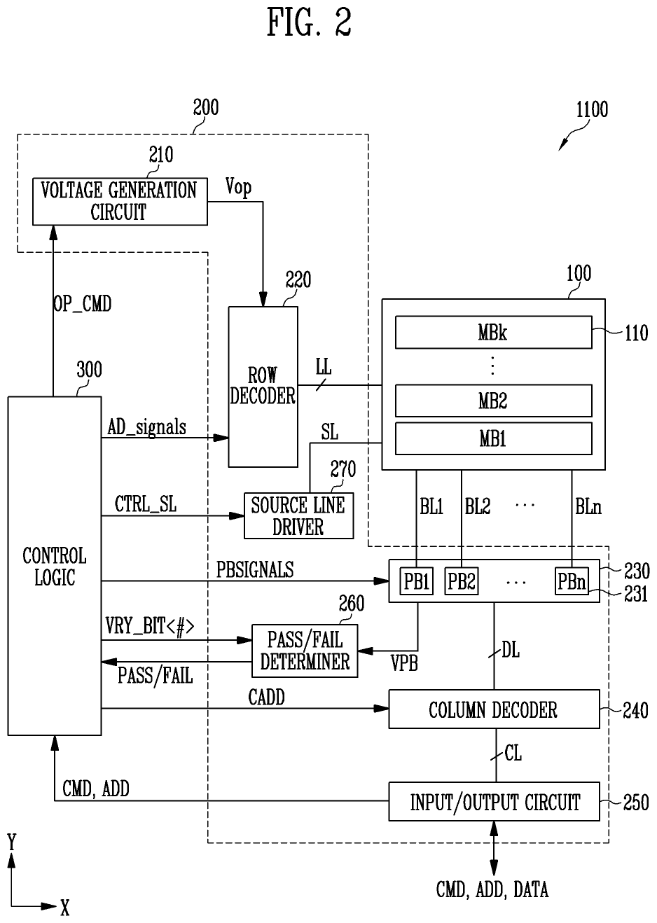

FIG. 2 is a diagram illustrating the memory device of FIG. 1.

Referring to FIG. 2, the memory device 1100 may include a memory cell array 100 in which data is stored. The memory device 1100 may include a peripheral circuit 200 configured to perform a program operation for storing data in the memory cell array 100, a read operation for outputting the stored data, and an erase operation for erasing the stored data. The memory device 1100 may include control logic 300 that controls the peripheral circuit 200 according to the control of the memory controller 1200 of FIG. 1. During the erase operation, the memory device 1100 according to an embodiment of the present disclosure may perform a first erase operation of applying a first erase voltage to a bit line and a source line of a selected memory block and a second erase operation of applying a second erase voltage to a bit line corresponding to erase-passed memory cells and applying the first erase voltage to a bit line corresponding to erase-failed memory cells after the first erase operation. The first erase voltage may be applied to the source line of the selected memory block during the second erase operation.

The memory cell array 100 may include a plurality of memory blocks 110, also denoted MB1 to MBk (k is a positive integer). Local lines LL and bit lines BL1 to BLn (n is a positive integer) may be connected to each of the memory blocks MB1 to MBk. For example, the local lines LL may include a first select line, a second select line, and a plurality of word lines arranged between the first and second select lines. In addition, the local lines LL may include dummy lines arranged between the first select line and the word lines, and between the second select line and the word lines. Here, the first select line may be a source select line, and the second select line may be a drain select line. For example, the local lines LL may include the word lines, the drain and source select lines, and source lines. For example, the local lines LL may further include the dummy lines. For example, the local lines LL may further include pipe lines. The local lines LL may be connected to the memory blocks MB1 to MBk, respectively, and the bit lines BL1 to BLn may be commonly connected to the memory blocks MB1 to MBk. The memory blocks MB1 to MBk may be implemented in a two-dimensional or three-dimensional structure. For example, the memory cells may be arranged in a direction parallel to a substrate in the memory block 110 in a two-dimensional structure. In another embodiment, the memory cells may be stacked in a direction perpendicular to the substrate in the memory block 110 to form a three-dimensional structure.

The peripheral circuit 200 may be configured to perform the program, read, and erase operations of the selected memory block 110 under control of the control logic 300. For example, the peripheral circuit 200 may include a voltage generation circuit 210, a row decoder 220, a page buffer group 230, a column decoder 240, an input/output circuit 250, a pass/fail determiner (pass/fail check circuit) 260, and a source line driver 270.

The voltage generation circuit 210 may generate various operation voltages Vop used in the program, read, and erase operations in response to an operation signal OP_CMD. In addition, the voltage generation circuit 210 may selectively discharge the local lines LL in response to the operation signal OP_CMD. For example, the voltage generation circuit 210 may generate a program voltage, a read voltage, a verify voltage, a pass voltage, and a select transistor operation voltage under the control of the control logic 300.

The row decoder 220 may transfer the operation voltages Vop to the local lines LL connected to the selected memory block 110 in response to row decoder control signals AD_signals. For example, the row decoder 220 may selectively apply the operation voltages (for example, the program voltage, the read voltage, the verify voltage, the pass voltage, and the like) generated by the voltage generation circuit 210 to the local lines LL in response to the row decoder control signals AD_signals, may float some of the local lines LL (for example, a word line and a source select line).

The page buffer group 230 may include a plurality of page buffers 231, also denoted PB1 to PBn, connected to the bit lines BL1 to BLn. The page buffers PB1 to PBn may operate in response to page buffer control signals PBSIGNALS. For example, the page buffers PB1 to PBn may control the bit lines BL1 to BLn in a floating state during an erase voltage application in the erase operation, and may sense a current or a potential level of the bit lines BL1 to BLn during an erase verify operation.

The page buffer group 230 may apply the first erase voltage or the second erase voltage to the bit lines BL1 to BLn during the erase operation. For example, the page buffer group 230 may apply the first erase voltage to the bit lines BL1 to BLn during the first erase operation, and may selectively apply the first erase voltage or the second erase voltage to the bit lines BL1 to BLn according to a result of the erase verify operation performed after the first erase operation. For example, the page buffer group 230 may apply the second erase voltage to the bit line connected to the memory cells determined as erase pass as the result of the erase verify operation and apply the first erase voltage to the bit lines connected to the memory cells determined as erase fail as the result of the erase verify operation. In another embodiment, the page buffer group 230 may control a bit line connected to the memory cells determined as erase pass as the result of the erase verify operation in a floating state. The page buffer group 230 may generate and output a sensing voltage VPB according to the result of the erase verify operation.

The column decoder 240 may transfer data between the input/output circuit 250 and the page buffer group 230 in response to a column address CADD. For example, the column decoder 240 may exchange data with the page buffers 231 through data lines DL, or may exchange data with the input/output circuit 250 through column lines CL.

The input/output circuit 250 may transfer the command CMD and the address ADD received from the memory controller 1200 of FIG. 1 to the control logic 300 or may exchange the data DATA with the column decoder 240.

During the read operation or the verify operation, the pass/fail determiner 260 may generate a reference current in response to a permission bit VRY_BIT<#>, compare a sensing voltage VPB received from the page buffer group 230 with a reference voltage generated by the reference current, and output a pass signal PASS or a fail signal FAIL.

The source line driver 270 may be connected to the memory cell included in the memory cell array 100 through the source line SL and may control a voltage applied to the source line SL. For example, during the erase operation, the source line driver 270 may generate the first erase voltage and apply the first erase voltage to the source line of the memory cell array 100.

The source line driver 270 may receive a source line control signal CTRL_SL from the control logic 300 and control a source line voltage applied to the source line SL based on the source line control signal CTRL_SL.

The control logic 300 may output the operation signal OP_CMD, the decoder control signals AD_signals, the page buffer control signals PBSIGNALS, and the permission bit VRY_BIT<#> in response to the command CMD and the address ADD to control the peripheral circuits 200. In addition, the control logic 300 may determine whether the verify operation is passed or failed in response to the pass signal PASS or the fail signal FAIL.

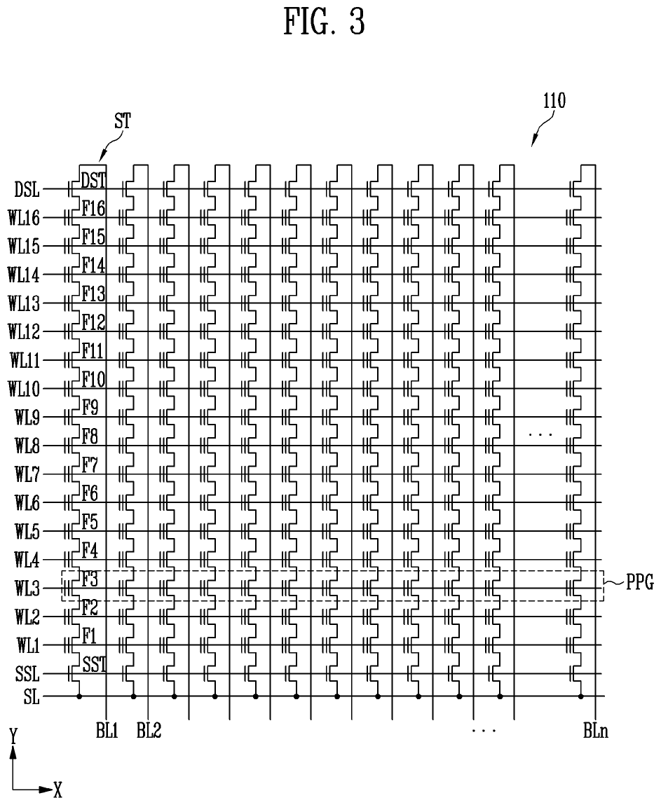

FIG. 3 is a diagram illustrating a representative memory block of FIG. 2.

Referring to FIG. 3, the memory block 110 may be connected to a plurality of word lines arranged in parallel with each other between the first select line and the second select line. Here, the first select line may be the source select line SSL, and the second select line may be the drain select line DSL. More specifically, the memory block 110 may include a plurality of strings ST connected between the bit lines BL1 to BLn and the source line SL. The bit lines BL1 to BLn may be connected to the strings ST, respectively, and the source line SL may be commonly connected to the strings ST. Since each of the strings ST may be configured the same, a string ST connected to the first bit line BL1 is specifically described, as an example.

The string ST may include a source select transistor SST, a plurality of memory cells F1 to F16, and a drain select transistor DST connected in series between the source line SL and the first bit line BL1. One string ST may include one or more of the source select transistor SST and the drain select transistor DST, and may include more than the 16 memory cells F1 to F16 shown in the figure.

A source of the source select transistor SST may be connected to the source line SL and a drain of the drain select transistor DST may be connected to the first bit line BL1. The memory cells F1 to F16 may be connected in series between the source select transistor SST and the drain select transistor DST. Gates of the source select transistors SST included in the different strings ST may be connected to the source select line SSL, gates of the drain select transistors DST may be connected to the drain select line DSL, and gates of the memory cells F1 to F16 may be connected to the plurality of word lines WL1 to WL16. A group of the memory cells connected to the same word line among the memory cells included in different strings ST may be referred to as a page PPG. Therefore, the memory block 11 may include the same number of pages PPG as word lines WL1 to WL16.

One memory cell may store 1 bit of data. This is commonly called a single level cell (SLC). In this case, one physical page PPG may store one logical page (LPG) data. The one logical page (LPG) data may include data bits of the same number as cells included in one physical page PPG. In addition, one memory cell may store two or more bits of data. This is commonly called a multi-level level cell (MLC). In this case, one physical page PPG may store two or more logical page (LPG) data.

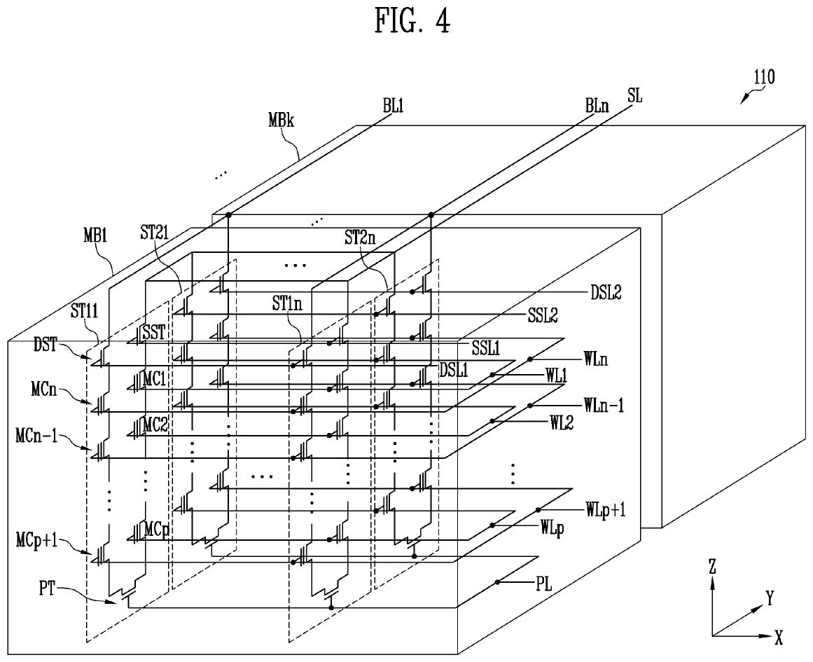

FIG. 4 is a diagram illustrating an embodiment of a memory block configured in three-dimensions.

Referring to FIG. 4, the memory cell array 100 may include a plurality of memory blocks 100 (MB1 to MBk). Each memory block 110 may include a plurality of strings ST11 to ST1n and ST21 to ST2n. In an embodiment, each of the plurality of strings ST11 to ST1n and ST21 to ST2n may be formed in a ‘U’ shape. In the first memory block MB1, n strings may be arranged in a row direction (X direction). In FIG. 4, two strings are arranged in a column direction (Y direction), but this is for clarity; three or more strings may be arranged in the column direction (Y direction).

Each of the plurality of strings ST11 to ST1n and ST21 to ST2n may include at least one source select transistor SST, first to n-th memory cells MC1 to MCn, a pipe transistor PT, and at least one drain select transistor DST.

The source and drain select transistors SST and DST and the memory cells MC1 to MCn may have similar structures. For example, each of the source and drain select transistors SST and DST and the memory cells MC1 to MCn may include a channel film, a tunnel insulating film, a charge trap film, and a blocking insulating film. For example, a pillar for providing the channel film may be provided in each string. For example, a pillar for providing at least one of the channel film, the tunnel insulating film, the charge trap film, and the blocking insulating film may be provided in each string.

The source select transistor SST of each string may be connected between the source line SL and the memory cells MC1 to MCp.

In an embodiment, the source select transistors of the strings arranged in the same row may be connected to the source select line extending in the row direction, and the source select transistors of the strings arranged in different rows may be connected to different source select lines. In FIG. 4, the source select transistors of the strings ST11 to ST1n of a first row may be connected to a first source select line SSL1. The source select transistors of the strings ST21 to ST2n of a second row may be connected to a second source select line SSL2.

In another embodiment, the source select transistors of the strings ST11 to ST1n and ST21 to ST2n may be commonly connected to one source select line.

The first to n-th memory cells MC1 to MCn of each string may be connected between the source select transistor SST and the drain select transistor DST.

The first to n-th memory cells MC1 to MCn may be divided into first to p-th memory cells MC1 to MCp and (p+1)-th to n-th memory cells MCp+1 to MCn. The first to p-th memory cells MC1 to MCp may be sequentially arranged in a vertical direction (Z direction), and may be connected in series between the source select transistor SST and the pipe transistor PT. The (p+1)-th to n-th memory cells MCp+1 to MCn may be sequentially arranged in the vertical direction (Z direction), and may be connected in series between the pipe transistor PT and the drain select transistor DST. The first to p-th memory cells MC1 to MCp and the (p+1)-th to n-th memory cells MCp+1 to MCn may be connected to each other through the pipe transistor PT. Gates of the first to n-th memory cells MC1 to MCn of each string may be connected to the first to the n-th word lines WL1 to WLn, respectively.

In an embodiment, at least one of the first to n-th memory cells MC1 to MCn may be used as a dummy memory cell. When the dummy memory cell is provided, a voltage or a current of a corresponding string may be stably controlled. A gate of the pipe transistor PT of each string may be connected to the pipeline PL.

The drain select transistor DST of each string may be connected between the bit line and the memory cells MCp+1 to MCn. The strings arranged in the row direction may be connected to the drain select line extending in the row direction. The drain select transistors of the strings ST11 to ST1n of the first row may be connected to a first drain select line DSL1. The drain select transistors of the strings ST21 to ST2n of the second row may be connected to a second drain select line DSL2.

The strings arranged in the column direction may be connected to the bit lines extending in the column direction. In FIG. 4, the strings ST11 and ST21 of a first column may be connected to the first bit line BL1. The strings ST1n and ST2n of an n-th column may be connected to the n-th bit line BLn.

Among the strings arranged in the row direction, the memory cells connected to the same word line may configure one page. For example, the memory cells connected to the first word line WL1 among the strings ST11 to ST1n of the first row may configure one page. The memory cells connected to the first word line WL1 among the strings ST21 to ST2n of the second row may configure another page. The strings arranged in one row direction are selected by selecting any one of the drain select lines DSL1 and DSL2. One page of the selected strings is selected by selecting any one of the word lines WL1 to WLn.

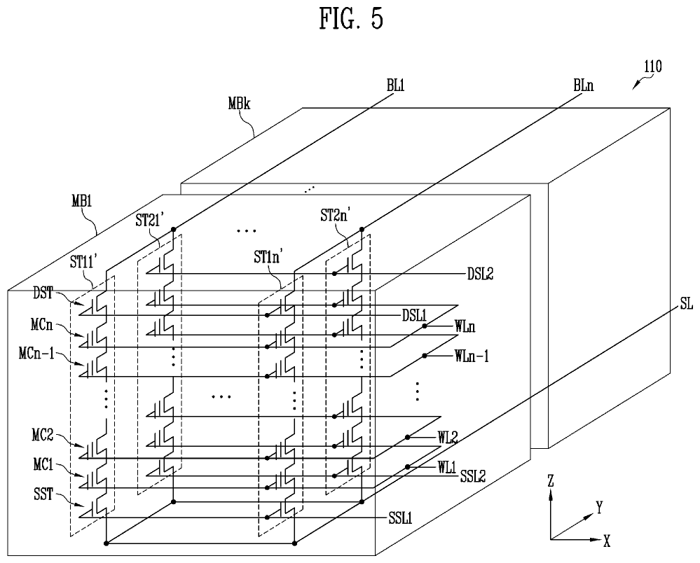

FIG. 5 is a diagram illustrating another embodiment of a memory block configured in three-dimensions.

Referring to FIG. 5, the memory cell array 100 may include a plurality of memory blocks 100 (MB1 to MBk). A representative memory block 110 may include a plurality of strings ST11′ to ST1n′ and ST21′ to ST2n′. Each of the plurality of strings ST11′ to ST1n′ and ST21′ to ST2n′ may be extended along the vertical direction (Z direction). In the memory block 110, n strings may be arranged in the row direction (X direction). In FIG. 5, two strings are arranged in the column direction (Y direction), but this is for clarity; three or more strings may be arranged in the column direction (Y direction).

Each of the plurality of strings ST11′ to ST1n′ and ST21′ to ST2n′ may include at least one source select transistor SST, first to n-th memory cells MC1 to MCn, and at least one drain select transistor DST.

The source select transistor SST of each string may be connected between the source line SL and the memory cells MC1 to MCn. The source select transistors of the strings arranged in the same row may be connected to the same source select line. The source select transistors of the strings ST11′ to ST1n′ arranged in the first row may be connected to a first source select line SSL1. The source select transistors of the strings ST21′ to ST2n′ arranged in the second row may be connected to a second source select line SSL2. In another embodiment, the source select transistors of the strings ST11′ to ST1n′ and ST21′ to ST2n′ may be commonly connected to one source select line.

The first to n-th memory cells MC1 to MCn of each string may be connected to each other in series between the source select transistor SST and the drain select transistor DST. Gates of the first to n-th memory cells MC1 to MCn may be connected to the first to n-th word lines WL1 to WLn, respectively.

In an embodiment, at least one of the first to n-th memory cells MC1 to MCn may be used as a dummy memory cell. When the dummy memory cell is provided, a voltage or a current of a corresponding string may be stably controlled. Therefore, reliability of the data stored in the memory block 110 may be improved.

The drain select transistor DST of each string may be connected between the bit line and the memory cells MC1 to MCn. The drain select transistors DST of the strings arranged in the row direction may be connected to the drain select line extending in the row direction. The drain select transistors DST of the strings ST11′ to ST1n′ of the first row may be connected to a first drain select line DSL1. The drain select transistors DST of the strings ST21′ to ST2n′ of the second row may be connected to a second drain select line DSL2.

That is, the memory block 110 of FIG. 5 may have an equivalent circuit similar to the memory block 110 of FIG. 4 except that the pipe transistor PT is excluded from each string.

The plurality of memory blocks MB1 to MBk described with reference to FIGS. 4 and 5 may share the source line SL.

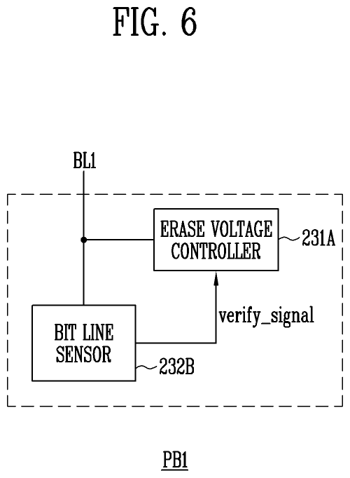

FIG. 6 is a diagram illustrating the page buffer of FIG. 2.

Each of the page buffers PB1 to PBn of FIG. 2 may be configured the same. Thus, the page buffer PB1 is described as an example.

Referring to FIG. 6, the page buffer PB1 may include an erase voltage controller 231A and a bit line sensor 232B.

The erase voltage controller 231A may be connected to a bit line BL1 and may apply the first erase voltage to the bit line BL1 during the first erase operation in the erase operation. In addition, the erase voltage controller 231A may apply the first erase voltage or the second erase voltage to the bit line BL1 in response to a verify signal (verify_signal) output from the bit line sensor 232B during the second erase operation performed after the first erase operation. For example, during the second erase operation, the erase voltage controller 231A may apply the second erase voltage to the bit line BL1 in response to the verify signal of a first logic level indicating erase pass as a result of the erase verify operation or apply the first erase voltage to the bit line BL1 in response to the verify signal of a second logic level indicating erase fail as the result of the erase verify operation. In another embodiment, the erase voltage controller 231A may control the bit line BL1 to a floating state in response to the verify signal of the first logic level indicating erase pass as the result of the erase verify operation during the second erase operation.

The bit line sensor 232B may be initialized before the first erase operation and generate and output the verify signal of the second logic level during the first erase operation. The bit line sensor 232B may perform the erase verify operation after the first erase operation and the second erase operation by sensing a voltage or a current amount of the bit line BL1. In addition, the bit line sensor 232B may generate and output the verify signal based on the result of the erase verify operation. For example, the bit line sensor 232B may verify whether memory cells included in a string corresponding to the bit line BL1 are erased with a threshold voltage equal to or less than a target level, by sensing the voltage or the current amount of the bit line BL1 during the erase verify operation. When all memory cells included in the string corresponding to the bit line BL1 are erased with the threshold voltage equal to or less than the target level, the bit line sensor 232B may determine that the memory cells have passed the erase operation (erase pass) and generate and output the verify signal of the first logic level. In addition, when one or more of the memory cells included in the string corresponding to the bit line BL1 has a threshold voltage greater than the target level, the bit line sensor 232B may determine that the memory cells have failed the erase operation (erase fail) and generate and output the verify signal of the second logic level.

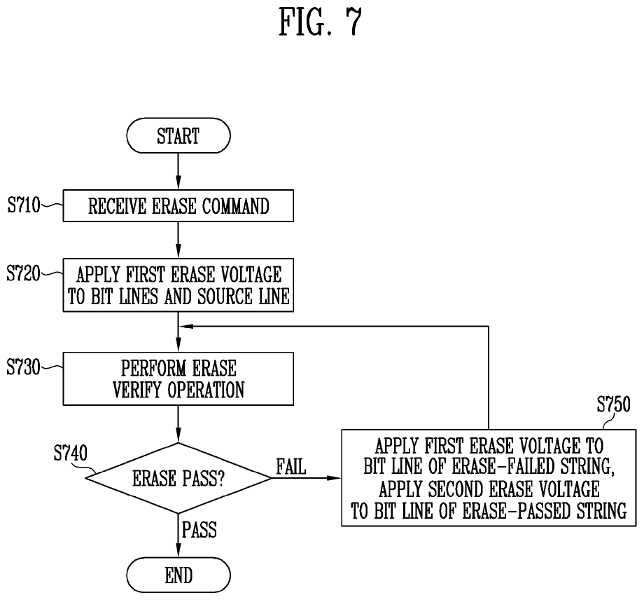

FIG. 7 is a flowchart illustrating an operation of the memory device according to an embodiment of the present disclosure.

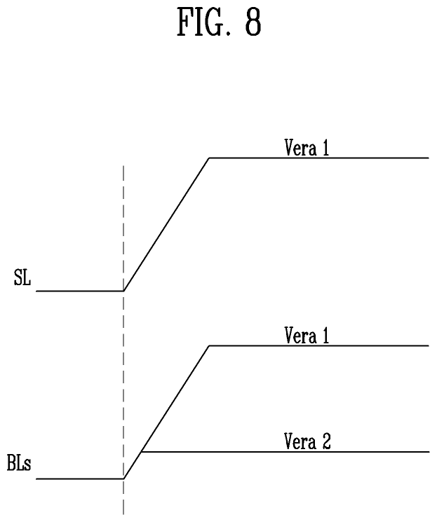

FIG. 8 is a diagram illustrating the first erase voltage and the second erase voltage applied to the source line and the bit line during the erase operation according to an embodiment of the present disclosure.

The method of operating the memory device according to an embodiment of the present disclosure is described with reference to FIGS. 1 to 8 as follows.

In operation S710, the memory controller 1200 generates an erase command CMD in response to an erase request from the host 2000 and transmits the generated erase command CMD to the memory device 1100. The memory controller 1200 transmits, along with the erase command CMD, an address ADD corresponding to a memory block (for example, MB1) to perform the erase operation to the memory device 1100.

In operation S720, the memory device 1100 performs the first erase operation of the selected memory block MB1 in response to the erase command CMD and the address ADD, and applies a first erase voltage Vera 1 to the source lines SL and the bit lines BL1 to BLn of the selected memory block MB1 during the first erase operation.

For example, during the first erase operation, the source line driver 270 applies the first erase voltage Vera 1 to the source line SL connected to the selected memory block MB1 based on the source line control signal CTRL_SL generated by the control logic 300. During the first erase operation, the page buffer group 230 applies the first erase voltage Vera 1 to the bit lines BL1 to BLn connected to the selected memory block MB1. For example, the bit line sensors 232B of each of the page buffers PB1 to PBn are initialized and generate and output the verify signal of the second logic level during the first erase operation. During the first erase operation, the erase voltage controllers 231A of each of the page buffers PB1 to PBn apply the first erase voltage Vera 1 to the corresponding bit lines BL1 to BLn in response to the verify signal of the second logic level. During the first erase operation, the row decoder 220 applies a turn-off voltage (for example, 0V) to the drain select lines DSL1 and DSL2 and the source select lines SSL1 and SSL2 of the selected memory block MB1. Therefore, a GIDL current is generated in a lower channel of the drain select transistors DST and the source select transistors SST included in the selected memory block MB1. The row decoder 220 applies an erase operation voltage (for example, 0V) to the word lines WL1 to WLn of the selected memory block MB1. Therefore, the GIDL current generated in the lower channel of the drain select transistors DST and the source select transistors SST flows into channels of the selected memory block MB1, and electrons stored in a charge storage layer of the memory cells MC1 to MCn are de-trapped by a potential difference between a gate and the channel of the memory cells MC1 to MCn. Accordingly, threshold voltages of the memory cells MC1 to MCn drop.

In operation S730, the memory device 1100 performs the erase verify operation on the selected memory block MB1.

During the erase verify operation, the voltage generation circuit 210 generates and outputs the verify voltage, and the row decoder 220 applies the verify voltage to the word lines WL1 to WLn of the selected memory block MB1. The page buffers PB1 to PBn of the page buffer group 230 sense a voltage or a current amount of the bit lines BL1 to BLn. For example, the bit line sensors 232B of each of the page buffers PB1 to PBn sense the voltage or the current amount of the corresponding bit line to determine erase pass or erase fail for the string ST corresponding to the bit line. For example, erase fail is determined when a threshold voltage of at least one of the plurality of memory cells MC1 to MCn included in the string ST is greater than a target threshold voltage, and erase pass is determined when a threshold voltage of all of the plurality of memory cells MC1 to MCn included in the string ST is equal to or less than the target threshold voltage. That is, during the erase verify operation, each of the page buffers PB1 to PBn may determine erase pass or erase fail of the corresponding string ST.

In operation S740, the control logic 300 determines the result of the erase verify operation. For example, the page buffer group 230 may generate and output the sensing voltage VPB according to the result of the erase verify operation, and the pass/fail determiner 260 may compare the sensing voltage VPB received from the page buffer group 230 with the reference voltage generated by the reference current to output the pass signal PASS or the fail signal FAIL. For example, during the erase verify operation, the control logic 300 may determine the selected memory block MB1 as erase pass when all strings ST in the selected memory block MB1 are determined as erase pass and the control logic 300 may determine the selected memory block MB1 as erase fail when at least one string among the strings ST in the selected memory block MB1 is determined as erase fail.

As the result of the erase verify operation of S740, when the selected memory block MB1 is determined as erase pass (pass), the erase operation ends.

As the result of the erase verify operation of S740, when at least one string among the strings ST included in the selected memory block MB1 is determined as erase fail and the selected memory block MB1 is thus determined as erase fail (fail), the memory device 1100 performs the second erase operation of the memory block MB1. During the second erase operation, the memory device 1100 applies the first erase voltage Vera 1 to the source line SL of the selected memory block MB1, applies the second erase voltage Vera 2 lower than the first erase voltage Vera 1 to the bit line corresponding to the erase-passed string ST among the bit lines BL1 to BLn, and applies the first erase voltage Vera 1 to the bit lines corresponding to the erase-failed string ST among the bit lines BL1 to BLn. The second erase voltage Vera 2 may be equal to or less than 5V.

For example, during the second erase operation, the source line driver 270 applies the first erase voltage Vera 1 to the source line SL connected to the selected memory block MB1 based on the source line control signal CTRL_SL generated by the control logic 300. During the second erase operation, the page buffer group 230 applies the first erase voltage Vera 1 or the second erase voltage Vera 2 to the bit lines BL1 to BLn connected to the selected memory block MB1. For example, the bit line sensors 232B of each of the page buffers PB1 to PBn generate and output the verify signal of the first logic level or the second logic level according to the result of the erase verify operation immediately before the second erase operation, and the erase voltage controllers 231A of each of the page buffers PB1 to PBn apply the first erase voltage Vera 1 or the second erase voltage Vera 2 to the corresponding bit lines BL1 to BLn in response to the verify signal. For example, when a corresponding string ST is determined as erase pass as the result of the erase verify operation, the bit line sensor 232B generates and outputs the verify signal of the first logic level, and the erase voltage controller 231A applies the second erase voltage Vera 2 to the corresponding bit line in response to the verify signal of the first logic level during the second erase operation. When the corresponding string ST is determined as erase fail as the result of the erase verify operation, the bit line sensor 232B generates and outputs the verify signal of the second logic level, and the erase voltage controller 231A applies the first erase voltage Vera 1 to the corresponding bit line in response to the verify signal of the second logic level during the second erase operation.

During the second erase operation, the row decoder 220 applies the turn-off voltage (for example, 0V) to the drain select lines DSL1 and DSL2 and the source select lines SSL1 and SSL2 of the selected memory block MB1. Therefore, the GIDL current is generated in the lower channel of the drain select transistors DST and the source select transistors SST included in the selected memory block MB1. The first erase voltage Vera 1 is applied to the bit line of the erase-failed string ST to generate a GIDL current amount similar to that of the first erase operation, the second erase voltage Vera 2 is applied to the bit line of the erase-passed string ST, and thus a generated GIDL current amount is relatively small as compared to the string ST to which the first erase voltage Vera 1 is applied. The row decoder 220 applies the erase operation voltage (for example, 0V) to the word lines WL1 to WLn of the selected memory block MB1. Therefore, the GIDL current generated in the lower channel of the drain select transistors DST and the source select transistors SST flows into the channels of the selected memory block MB1, and electrons stored in the charge storage layer of the memory cells MC1 to MCn are de-trapped by the potential difference between the gate and the channel of the memory cells MC1 to MCn. Accordingly, the threshold voltages of the memory cells MC1 to MCn drop. A relatively small GIDL current flows into the channel of the erase-passed string ST as compared to the erase-failed string ST, and thus the threshold voltages of the memory cells MC1 to MCn included in the erase-passed string ST drop less than the threshold voltages of the memory cells MC1 to MCn included in the erase-failed string ST. Therefore, a phenomenon of over-erasing, during the second erase operation, the memory cells of the string ST, which are determined as erase pass as a result of the first erase operation, may be suppressed.

After performing the above-described second erase operation, the above-described erase verify operation (S730) and subsequent operations are performed again.

In the above-described embodiments of the present disclosure, the second erase voltage is applied to the bit line of the string determined as erase pass during the second erase operation, but in another embodiment, the bit line of the string determined as erase pass may be controlled to float during the second erase operation.

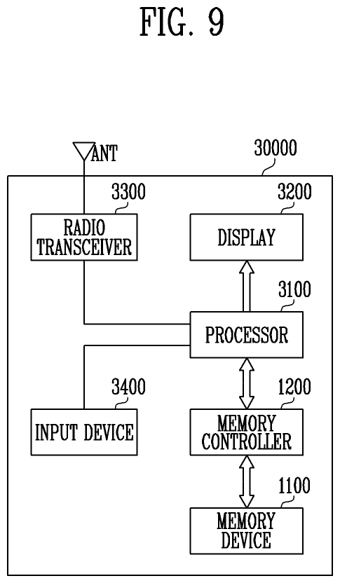

FIG. 9 is a diagram illustrating another embodiment of the memory system including the memory device shown in FIG. 2.

Referring to FIG. 9, the memory system 30000 may be implemented as a cellular phone, a smart phone, a tablet PC, a personal digital assistant (PDA) or a wireless communication device. The memory system 30000 may include the memory device 1100 and the memory controller 1200 capable of controlling the operation of the memory device 1100. The memory controller 1200 may control a data access operation, for example, a program operation, an erase operation, or a read operation, of the memory device 1100 under control of a processor 3100.

Data programmed in the memory device 1100 may be output through a display 3200 under the control of the memory controller 1200.

A radio transceiver 3300 may transmit and receive a radio signal through an antenna ANT. For example, the radio transceiver 3300 may convert a radio signal received through the antenna ANT into a signal that may be processed by the processor 3100. Therefore, the processor 3100 may process the signal output from the radio transceiver 3300 and transmit the processed signal to the memory controller 1200 or the display 3200. The memory controller 1200 may program the signal processed by the processor 3100 to the memory device 1100. In addition, the radio transceiver 3300 may convert a signal output from the processor 3100 into a radio signal, and output the radio signal to an external device through the antenna ANT. An input device 3400 may be a device capable of inputting a control signal for controlling the operation of the processor 3100 or data to be processed by the processor 3100. The input device 3400 may be implemented as a pointing device such as a touch pad or a computer mouse, a keypad, or a keyboard. The processor 3100 may control an operation of the display 3200 so that data output from the memory controller 1200, data output from the radio transceiver 3300, or data output from the input device 3400 is output through the display 3200.

According to an embodiment, the memory controller 1200 capable of controlling the operation of memory device 1100 may be implemented as a part of the processor 3100 and may also be implemented as a chip separate from the processor 3100.

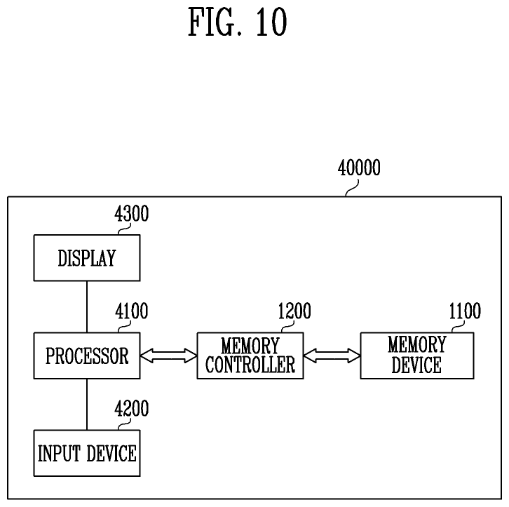

FIG. 10 is a diagram illustrating another embodiment of the memory system including the memory device shown in FIG. 2.

Referring to FIG. 10, the memory system 40000 may be implemented as a personal computer (PC), a tablet PC, a net-book, an e-reader, a personal digital assistant (PDA), a portable multimedia player (PMP), an MP3 player, or an MP4 player.

The memory system 40000 may include the memory device 1100 and the memory controller 1200 capable of controlling a data process operation of the memory device 1100.

A processor 4100 may output data stored in the memory device 1100 through a display 4300, according to data input through an input device 4200. For example, the input device 4200 may be implemented as a point device such as a touch pad or a computer mouse, a keypad, or a keyboard.

The processor 4100 may control the overall operation of the memory system 40000 and control the operation of the memory controller 1200. According to an embodiment, the memory controller 1200 capable of controlling the operation of memory device 1100 may be implemented as a part of the processor 4100 or may be implemented as a chip separate from the processor 4100.

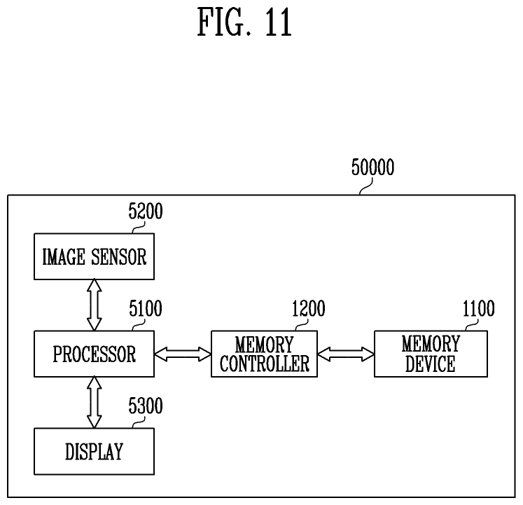

FIG. 11 is a diagram illustrating another embodiment of the memory system including the memory device shown in FIG. 2.

Referring to FIG. 11, the memory system 50000 may be implemented as an image processing device, for example, a digital camera, a portable phone provided with a digital camera, a smart phone provided with a digital camera, or a tablet PC provided with a digital camera.

The memory system 50000 includes the memory device 1100 and the memory controller 1200 capable of controlling a data process operation, for example, a program operation, an erase operation, or a read operation, of the memory device 1100.

An image sensor 5200 of the memory system 50000 may convert an optical image into digital signals. The digital signals may be transmitted to a processor 5100 or the memory controller 1200. Under control of the processor 5100, the digital signals may be output through a display 5300 or stored in the memory device 1100 through the memory controller 1200. In addition, data stored in the memory device 1100 may be output through the display 5300 under the control of the processor 5100 or the memory controller 1200.

According to an embodiment, the memory controller 1200 capable of controlling the operation of memory device 1100 may be implemented as a part of the processor 5100 or may be implemented as a chip separate from the processor 5100.

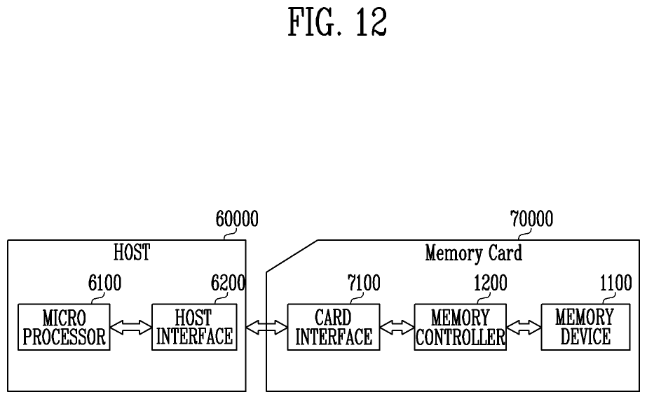

FIG. 12 is a diagram illustrating another embodiment of the memory system including the memory device shown in FIG. 2.

Referring to FIG. 12, the memory system 70000 may be implemented as a memory card or a smart card. The memory system 70000 may include the memory device 1100, the memory controller 1200, and a card interface 7100.

The memory controller 1200 may control data exchange between the memory device 1100 and the card interface 7100. According to an embodiment, the card interface 7100 may be a secure digital (SD) card interface or a multi-media card (MMC) interface, but is not limited thereto.

The card interface 7100 may interface data exchange between a host 60000 and the memory controller 1200 according to a protocol of the host 60000. According to an embodiment, the card interface 7100 may support a universal serial bus (USB) protocol, and an interchip (IC)-USB protocol. Here, the card interface may refer to hardware capable of supporting a protocol that is used by the host 60000, software installed in the hardware, or a signal transmission method.

When the memory system 70000 is connected to a host interface 6200 of the host 60000 such as a PC, a tablet PC, a digital camera, a digital audio player, a mobile phone, a console video game hardware, or a digital set-top box, the interface 6200 may perform data communication with the memory device 1100 through the card interface 7100 and the memory controller 1200 under control of a microprocessor 6100.

Although specific embodiments have been illustrated and described, various modifications may be possible without departing from the scope and technical spirit of the present disclosure. Therefore, the scope of the present invention is not limited to the above-described embodiments. Rather, the present invention encompasses all modifications and variations that fall within the scope of the claims.

What is claimed is:

1. A memory device comprising:
a memory block including a plurality of strings;
a peripheral circuit configured to perform an erase operation including a first erase operation, an erase verify operation, and a second erase operation on the memory block; and
control logic configured to control the peripheral circuit to perform the erase operation,
wherein, during the second erase operation, the control logic controls the peripheral circuit to apply a first erase voltage to a source line of the memory block and apply a second erase voltage, which is lower than the first erase voltage, to a bit line connected to a string determined as erase pass among the plurality of strings.

2. The memory device of claim 1, wherein the control logic controls the peripheral circuit to perform the erase verify operation after the first erase operation and to perform the second erase operation when it is determined that the erase verify operation failed.

3. The memory device of claim 1, wherein the control logic controls the peripheral circuit to apply the first erase voltage to the source line of the memory block and the bit lines of the memory block during the first erase operation.

4. The memory device of claim 1, wherein the peripheral circuit comprises:
a source line driver configured to apply the first erase voltage to the source line under control of the control logic; and
page buffers configured to apply the first erase voltage or the second erase voltage to the bit lines connected to the plurality of strings under the control of the control logic.

5. The memory device of claim 4,
wherein each of the page buffers is connected to a corresponding bit line among the bit lines, and
wherein each of the page buffers comprises:
an erase voltage controller configured to apply the first erase voltage or the second erase voltage to the corresponding bit line in response to a verify signal; and
a bit line sensor configured to sense a potential or a current amount of the corresponding bit line through the corresponding bit line during the erase verify operation and generate the verify signal according to a sensing result.

6. The memory device of claim 5, wherein the bit line sensor generates the verify signal of a first logic level when a corresponding string is determined as erase pass as the sensing result, and generates the verify signal of a second logic level when the corresponding string is determined as erase fail.

7. The memory device of claim 6, wherein the bit line sensor generates the verify signal of the second logic level during the first erase operation.

8. The memory device of claim 6, wherein, during the second erase operation, the erase voltage controller applies the second erase voltage to the corresponding bit line in response to the verify signal of the first logic level or applies the first erase voltage to the corresponding bit line in response to the verify signal of the second logic level.

9. The memory device of claim 1, wherein the control logic controls the peripheral circuit to end the erase operation of the memory block when all of the plurality of strings are determined as erase pass during the erase verify operation and perform the second erase operation when at least one string among the plurality of strings is determined as erase fail.

10. A memory device comprising:
a memory block including a plurality of strings;
a peripheral circuit configured to perform an erase operation including a first erase operation, an erase verify operation, and a second erase operation on the memory block; and
a control logic configured to control the peripheral circuit to perform the erase operation,
wherein, during the second erase operation, the control logic controls the peripheral circuit to apply an erase voltage to a source line of the memory block and float a bit line connected to a string determined as erase pass among the plurality of strings.

11. The memory device of claim 10, wherein the control logic controls the peripheral circuit to perform the erase verify operation after the first erase operation and to perform the second erase operation when it is determined that the erase verify operation failed.

12. The memory device of claim 10, wherein the peripheral circuit comprises:
a source line driver configured to apply the erase voltage to the source line under control of the control logic; and
page buffers configured to apply the erase voltage to the bit lines connected to the plurality of strings or float the bit lines under the control of the control logic.

13. The memory device of claim 12,
wherein each of the page buffers is connected to a corresponding bit line among the bit lines, and
wherein each of the page buffers comprises:
an erase voltage controller configured to apply the erase voltage to the corresponding bit line in response to a verify signal; and
a bit line sensor configured to sense a potential or a current amount of the corresponding bit line through the corresponding bit line during the erase verify operation and generate the verify signal according to a sensing result.

14. The memory device of claim 13, wherein the bit line sensor generates the verify signal of a first logic level when a corresponding string is determined as erase pass as the sensing result, and generates the verify signal of a second logic level when the corresponding string is determined as erase fail.

15. The memory device of claim 14, wherein the bit line sensor generates the verify signal of the second logic level during the first erase operation.

16. The memory device of claim 14, wherein, during the second erase operation, the erase voltage controller floats the corresponding bit line in response to the verify signal of the first logic level or applies the erase voltage to the corresponding bit line in response to the verify signal of the second logic level.

17. A method of operating a memory device, the method comprising:
performing a first erase operation of applying a first erase voltage to a source line and bit lines of a selected memory block;
determining whether each of a plurality of strings included in the selected memory block is erased by performing an erase verify operation; and
performing a second erase operation of applying the first erase voltage to the source line and applying a second erase voltage to a bit line of a string determined as erase pass when at least one string among the plurality of strings is determined as erase fail as a result of the erase verify operation.

18. The method of claim 17, wherein the first erase voltage is applied to a bit line of a string determined as erase fail among the plurality of strings during the second erase operation.

19. The method of claim 17, wherein the second erase voltage is lower than the first erase voltage.

20. A method of operating a memory device, the method comprising:
performing a first erase operation of applying an erase voltage to a source line and bit lines of a selected memory block;
determining whether each of a plurality of strings included in the selected memory block is erased by performing an erase verify operation; and
performing a second erase operation of applying the erase voltage to the source line, floating a bit line of a string determined as erase pass, and applying the erase voltage to a bit line of a string determined as erase fail when at least one string among the plurality of strings is determined as erase fail as a result of the erase verify operation.
